(19) United States
(12) Patent Application Publication
(10) Pub. No.: US 2006/0263976 A1
(43) Pub. Date: Nov. 23, 2006

(54) Semiconductor device with capacitor structure for improving area utilization

(76) Inventor: Shuji Sakamoto, Tokyo (JP)

Correspondence Address: BRUCE L. ADAMS, ESQ., SUITE 1231, 17 BATTERY PLACE, NEW YORK, NY, 10004, US

(21) Appl. No.: 11/353,923

(22) Filed: Feb. 14, 2006

(30) Foreign Application Priority Data
Feb. 15, 2005 (JP) 2005-38172

(51) Int. Cl. H01L 21/8242; H01L 27/108

(52) U.S. Cl. 438/253; 257/303

(57) ABSTRACT

A semiconductor device with a capacitor structure for improving area utilization comprises a plurality of electrically conductive layers and a plurality of dielectric layers. The dielectric layers and the electrically conductive layers are alternately superposed one over another, and the electrically conductive layers are alternately electrically connected.

### BACKGROUND OF THE INVENTION

1. Field of the Invention

The invention relates generally to a semiconductor device with a capacitor and, in particular, to the structure of the capacitor.

2. Description of the Related Art

A capacitor in an existing semiconductor device generally has a structure where, above and below an insulating layer that constitutes a dielectric layer, electrically conductive layers constituting a pair of electrodes are formed. A capacitance value of the capacitor is determined by the dielectric constant of the dielectric layer and the area size of the capacitor. The “area size” means the overlapping facing area of the opposed electrically conductive layers that sandwich the dielectric layer. (See Japanese Unexamined Patent Application Publication No. JP-A-5-190766).

### SUMMARY OF THE INVENTION

In the prior art capacitor structure, assuming the condition that the dielectric constants are same, in order to increase the capacitance value, the facing area of the respective electrically conductive layers has to be increased. That is, in order to obtain a capacitor having a larger capacitance value, a larger area size is necessary. Accordingly, in order to form a capacitor that has a large capacitance value, a problem of larger-sized semiconductor devices cannot be avoided. The present invention seeks to overcome this problem and provides a capacitor structure that, without increasing semiconductor device size, can obtain a large capacitance value.

In order to achieve the foregoing and other objects, according to a first aspect of the present invention, a capacitor structure includes a plurality of electrically conductive layers and a plurality of dielectric layers, wherein the dielectric layers and the electrically conductive layers are alternately superposed one over another, and the electrically conductive layers are alternately electrically connected.

Similarly, in order to achieve the foregoing and other objects, according to a second aspect of the present invention, a semiconductor device with a capacitor structure which includes a dielectric layer sandwiched between a first capacitor electrode and a second capacitor electrode, comprises a first capacitor portion including a diffusion region formed in a semiconductor substrate, a first dielectric layer formed on the diffusion region, and the second capacitor electrode formed on the first dielectric layer; and a second capacitor portion including the second capacitor electrode, a second dielectric layer formed on the second capacitor electrode, and a conductive layer formed on the second dielectric layer; wherein the diffusion region and the conductive layer are electrically connected to each other such that the diffusion region and the conductive layer comprise the first capacitor electrode.

Furthermore, in a capacitor structure involving a third aspect of the present invention, in the semiconductor device according to the second aspect of the invention, the diffusion region and the conductive layer are connected by a metal layer.

According to the first and second aspects of the present invention, the facing area of the electrically conductive layers that constitute a pair of electrodes that face each other with the dielectric layer interposed therebetween can be increased not planarly but superposedly. Accordingly, without enlarging the semiconductor device, a capacitor having a large capacitance value can be obtained.

According to the third aspect of the present invention, in addition to the above advantages, electrical connections between the electrically conductive layers can be more assuredly carried out.

### BRIEF DESCRIPTION OF THE DRAWINGS

FIG. 1 is a schematic sectional view of a semiconductor device with a capacitor according to one embodiment of the present invention.

FIG. 2 is a schematic plan view of the semiconductor device with a capacitor shown in FIG. 1.

FIG. 3 is an explanatory circuit diagram for explaining the constitution of the capacitor in the embodiment shown in FIGS. 1-2.

FIG. 4 is an explanatory circuit diagram for explaining the constitution of a capacitor in another embodiment of the present invention.

### DETAILED DESCRIPTION OF THE INVENTION

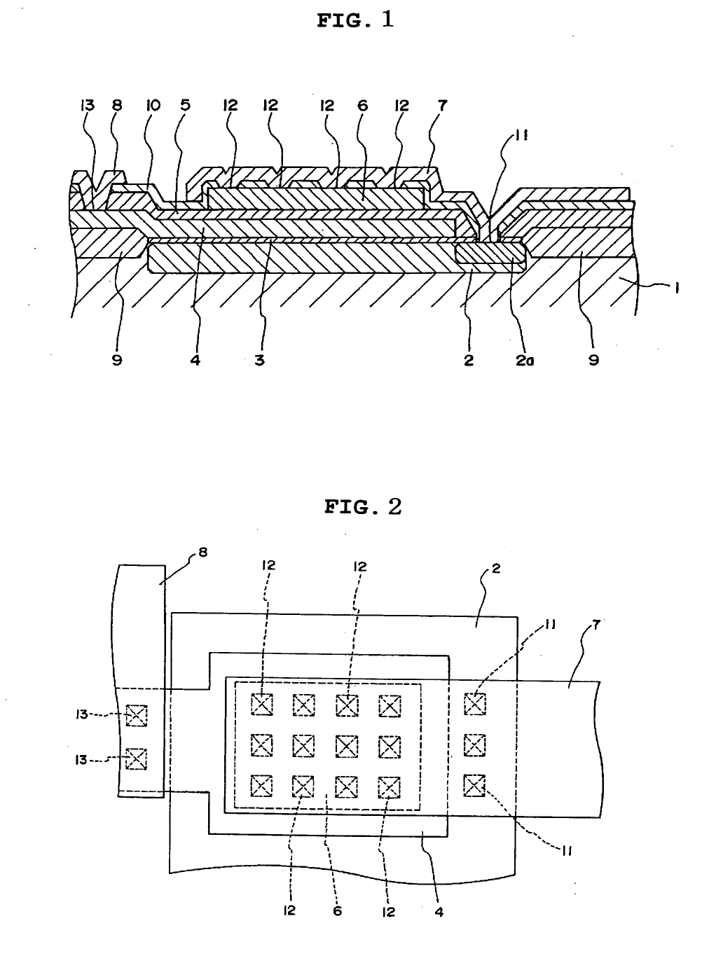

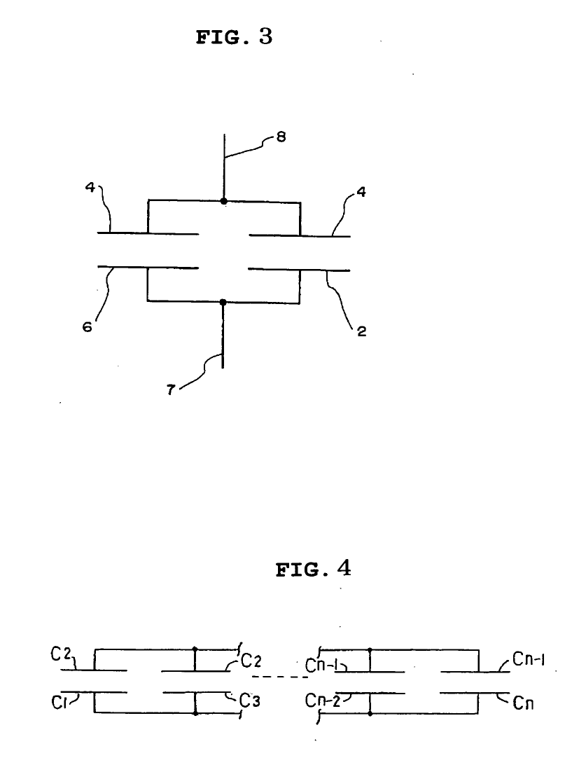

Now, preferred embodiments of the invention will be described with reference to FIGS. 1 through 3. FIG. 1 is a schematic sectional view of a semiconductor device with a capacitor, FIG. 2 is a plan view thereof, and FIG. 3 is a circuit diagram for explaining the constitution of the capacitor.

As shown in FIG. 1, on a silicon substrate 1 of a semiconductor device, impurity ions such as arsenic or phosphorus are implanted to form an N-diffusion layer 2 and a diffusion region 2a where the impurity ions are partially implanted at a high concentration. The diffusion layer 2 constitutes an electrically conductive layer, and a first insulating layer 3 comprised, for example, of silicon oxide is formed on and overlies the electrically conductive diffusion layer 2. A lower electrically conductive layer 4, preferably comprised of polysilicon, is formed on and overlies the first insulating layer 3. Thereby, a first capacitor is formed having the first insulating layer 3 as a dielectric layer sandwiched between the diffusion layer 2 and the lower electrically conductive layer 4 as a pair of electrodes.

On the lower electrically conductive layer 4, a second insulating layer 5 is formed, the second insulating layer 5 overlying the electrically conductive layer 4 and being comprised, for example, of silicon oxide. On the second insulating layer 5, an upper electrically conductive layer 6 is formed, the conductive layer 6 overlying the second insulating layer 5 and preferably being comprised of polysilicon. Thereby, a second capacitor is formed having the second insulating layer 5 as a dielectric layer sandwiched between the lower electrically conductive layer 4 and the upper electrically conductive layer 6 as a pair of electrodes. The lower electrically conductive layer 4 is an electrode common for both capacitors.

An insulating layer 10 comprised, for example, of silicon oxide is formed on both the upper electrically conductive layer 6 and the second insulating layer 5, and the upper electrically conductive layer 6 and the high concentration region 2a of the diffusion layer 2 are electrically connected with a wiring 7 of metal such as aluminum. By such a construction, as shown in FIG. 3, two superposed capacitors are formed that share the common electrode 4 and are connected in parallel with each other.

In FIGS. 1 and 2, reference numeral 11 denotes a contact region between the metal wiring 7 and the high concentration region 2a, and reference numeral 12 denotes a contact region between the metal wiring 7 and the upper electrically conductive layer 6. Furthermore, as understood from FIGS. 1 and 2, the lower electrically conductive layer 4 is electrically connected to an electrode of a MOS transistor formed on the silicon substrate 1 by a wiring 8 of metal, such as aluminum, in a contact region 13. In FIG. 1, reference numeral 9 denotes a LOCOS element isolation region.

In the embodiment described above, a first capacitor having the diffusion layer 2 and the lower electrically conductive layer 4 as a pair of electrodes and a second capacitor having the lower electrically conductive layer 4 and the upper electrically conductive layer 6 as a pair of electrodes are superposedly formed, and the diffusion layer 2 and the upper electrically conductive layer 6 are electrically connected. By such a construction, without horizontally expanding facing electrically conductive layers 2, 4 and 4, 6 that constitute pairs of opposed electrodes, the facing area of the opposed electrodes can be increased. That is, when compared with a capacitor that occupies the same area in a horizontal direction of the opposed electrodes, a capacitor having substantially two times the capacitance value can be obtained.

The present invention is not restricted to the above embodiment. For instance, the diffusion layer 2 and the electrically conductive layer 6 can be electrically connected not through the metal wiring 7 but directly. When the diffusion layer 2 and the electrically conductive layer 6 are directly electrically connected together rather than indirectly connected through the metal wiring 7, the high concentration region 2a of the diffusion layer 2 can be dispensed with. Furthermore, the number of superposed capacitors is not restricted to two and may be three or more. In this case, as shown in FIG. 4, electrically conductive layers, C1 through Cn, which are located above and below one another, are alternately electrically connected.

What is claimed is:

1. A semiconductor device with a capacitor structure having improved area utilization, comprising: a plurality of electrically conductive layers and a plurality of dielectric layers, wherein the dielectric layers and the electrically conductive layers are alternately superposed one over another, and the electrically conductive layers are alternately electrically connected.

2. A semiconductor device with a capacitor structure which includes a dielectric layer sandwiched between a first capacitor electrode and a second capacitor electrode, comprising:
a first capacitor portion including a diffusion region formed in a semiconductor substrate, a first dielectric layer formed on the diffusion region, and the second capacitor electrode formed on the first dielectric layer; and
a second capacitor portion including the second capacitor electrode, a second dielectric layer formed on the second capacitor electrode, and a conductive layer formed on the second dielectric layer,
wherein the diffusion region and the conductive layer are electrically connected to each other such that the diffusion region and the conductive layer comprise the first capacitor electrode.

3. A semiconductor device according to claim 2; wherein the diffusion region and the conductive layer are connected by a metal layer.

4. A semiconductor device having first and second superposed capacitors, comprising: a semiconductor substrate; an electrically conductive diffusion layer formed in the semiconductor substrate and constituting an electrode of the first capacitor; a first dielectric layer formed on and overlying the electrode; an electrically conductive layer formed on and overlying the dielectric layer and constituting a common electrode of the first and second capacitors; a second dielectric layer formed on and overlying the common electrode; and an electrically conductive layer formed on and overlying the second dielectric layer and constituting an electrode of the second capacitor.

5. A semiconductor device according to claim 4; further including a metal layer connecting the electrically conductive diffusion layer to the electrically conductive layer formed on the second dielectric layer.
